(19) United States
(12) Patent Application Publication
(10) Pub. No.: US 2015/0017805 A1
(43) Pub. Date: Jan. 15, 2015

(54) WAFER PROCESSING APPARATUS HAVING INDEPENDENTLY ROTATABLE WAFER SUPPORT AND PROCESSING DISH

(71) Applicant: Raymon F. Thompson, Kalispell, MT (US)

(72) Inventor: Raymon F. Thompson, Kalispell, MT (US)

(21) Appl. No.: 13/937,816

(22) Filed: Jul. 9, 2013

(51) Int. Cl. H01L 21/67; H01L 21/306

(52) U.S. Cl. CPC H01L 21/67086; H01L 21/30604; H01L 21/67115
USPC 438/689; 118/641

(57) ABSTRACT

An apparatus for processing a wafer is disclosed that includes a wafer support and a processing base. The wafer support is configured to support a wafer in a processing position, and to rotate the wafer about a first substantially vertical axis while in the processing position. The processing base includes a shallow dish configured to receive processing chemistry. The wafer support places the wafer in contact with the processing chemistry while in the processing position. The shallow dish is rotatable about a second substantially vertical axis when the wafer support is in the processing position. The rotation of the wafer is independent of the rotation of the shallow dish. Further, the processing base may include a heating element, such as an infrared heating element, that is disposed to locally elevate the temperature of of the shallow dish and chemistry contained in it.

### BACKGROUND

Semiconductor devices are used in a wide range of consumer electronics, computers, communication equipment, and various other products. They are made from silicon, or other semiconductor materials, that are often in the form of disc-shaped wafers. The wafers undergo many manufacturing processes to form the microelectronic circuits. During various manufacturing steps, the wafers are processed using fluid chemicals (e.g., acids, caustics, etchants, photoresists, plating solutions, purified water, etc.) as well as gaseous chemicals. They are also rinsed and dried to remove contaminants which can cause defects in the end product devices or otherwise interfere with subsequent process steps.

As greater emphasis is placed on the scaling down the size of microelectronics circuits, new processes must be developed and the accuracy of existing processes must be honed. However, current single wafer processing apparatus increasingly do not meet these demands. The designs of such single wafer processing apparatus make it difficult to improve the accuracy of the processes they perform. Further, such single wafer processing apparatus often use an excessive amount of processing chemistry beyond that needed to execute their processing operations. Wasted chemistry is both uneconomical and, if caustic, a hazard to the environment.

### SUMMARY

An apparatus for processing a wafer is disclosed that includes a wafer support and a processing base. The wafer support is configured to support a wafer in a processing position, and to rotate the wafer about a first substantially vertical axis while in the processing position. The processing base includes a shallow dish configured to receive processing chemistry. The wafer support places the wafer in contact with the processing chemistry while in the processing position. The shallow dish is rotatable about a second substantially vertical axis when the wafer support is in the processing position. The rotation of the wafer is independent of the rotation of the shallow dish. Further, the processing base may include a heating element, such as an infrared heating element, that is disposed to locally elevate the temperature of of the shallow dish and chemistry contained in it.

The features, functions, and advantages that are discussed below can be achieved independently in various embodiments or may be combined in yet other embodiments further details of which can be determined with reference to the following description and drawings.

### BRIEF DESCRIPTION OF THE DRAWINGS

FIG. 1 illustrates an apparatus for processing a wafer in which the wafer support is in an elevated position.

FIG. 2 illustrates an apparatus for processing a wafer in which the wafer support is in a processing position relative to a processing base.

FIGS. 3A and 3B are cross-sectional views showing various components that may be used in one embodiment of a dish assembly and wafer support.

FIGS. 4A and 4B show one embodiment of a shallow dish.

FIGS. 5A and 5B are cross-sectional views of one embodiment of section C when the wafer support is in a fully engaged processing position.

FIGS. 6A and 6B are cross-sectional views of one embodiment of section C when the wafer is supported at a first intermediate processing position.

FIGS. 7A and 7B are cross-sectional views of one embodiment of section C when the wafer is supported at a second intermediate processing position.

FIG. 8 is a flowchart of one manner in which a wafer may be processed.

### DETAILED DESCRIPTION

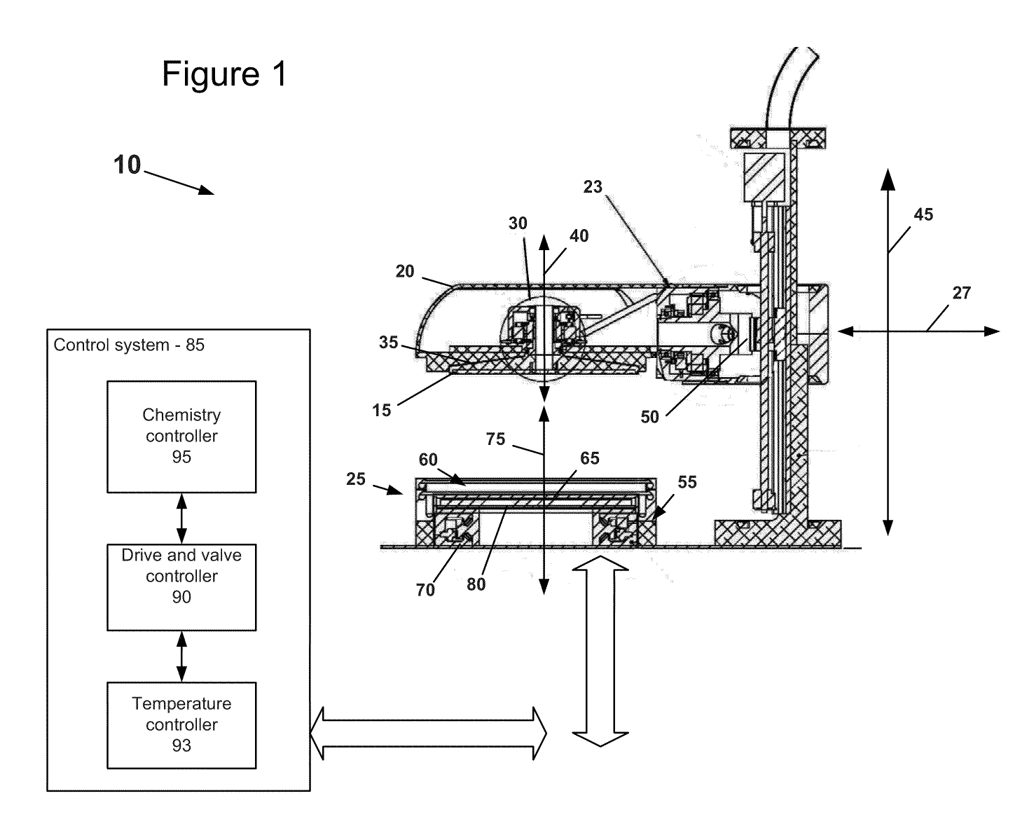

FIG. 1 shows an apparatus 10 for processing a wafer 15. Apparatus 10 includes a wafer head 20 and a processing base 25. The wafer head 20 may be configured with a motor 23 to rotate the wafer 15 about axis 27 from a first position in which the wafer 15 is received by the wafer head 20 in a face up orientation, and a second position in which the wafer 15 is disposed face down toward the processing base 25. A further motor 30 of the wafer head 20 is connected to a wafer support 35, such as a vacuum chuck, to rotate the wafer 15 about a substantially vertical axis 40.

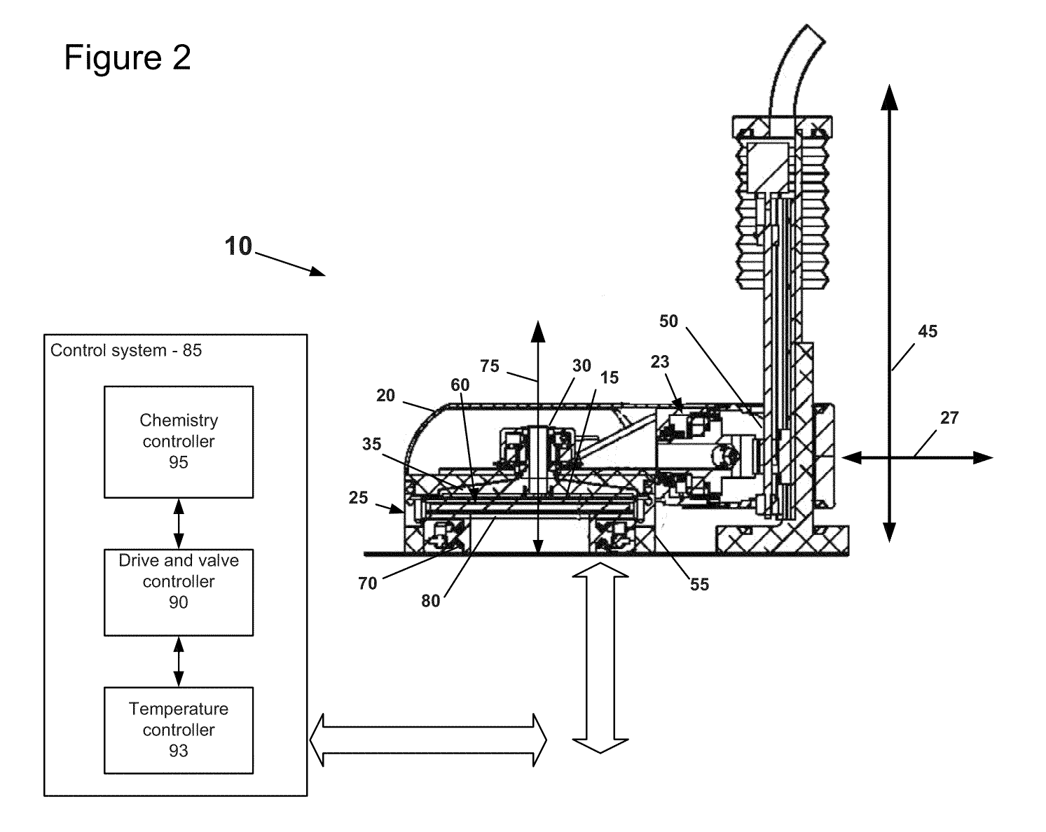

The wafer head 20 may also be driven along axis 45 by a still further motor 50. In this example, motor 50 is configured to drive the wafer head 20 and corresponding wafer support 35 between the elevated position shown in FIG. 1 and the processing position shown in FIG. 2.

The processing base 25 includes an outer shell assembly 55 that surrounds a dish assembly 60. The outer shell assembly 55 includes passages through which processing chemistry may be accepted from dish assembly 60 and recirculated and/or removed from the processing base 25. The dish assembly 60 includes a shallow dish 65 configured for rotation by motor 70 about a substantially vertical axis 75. In the embodiment of FIGS. 1 and 2, vertical axes 40 and 75 are coaxial. However, the axes may be offset vertically and/or horizontally from one another depending on process specifications.

In certain processes, the temperature of the chemistry in the shallow dish 65 may need to be elevated. Heating may occur in a pre-heating operation exterior to the shallow dish 65. In the embodiment of the dish assembly 60 shown in FIGS. 1 and 2, a heating element 80 is disposed at a position adjacent to the shallow dish 65 to provide local heating of the shallow dish 65 and, as a result, the processing chemistry supplied to it.

A control system 85 may govern the operation of the apparatus 10. In one example, the control system 85 includes a drive/valve controller 90, a temperature controller 93, and a chemistry controller 95. The drive/valve controller 90 may direct operation of the various motors of the apparatus 10. These operations may include: 1) elevating the wafer head 20 along axis 45 and rotating it to a wafer face-up orientation about axis 27 to receive the wafer to be processed on the wafer support 35; and 2) rotating the wafer head about axis 27 to a wafer face-down orientation and driving it along axis 45 to place the wafer in the processing position with respect to the processing base 25. The drive/valve controller 90 may also direct the valves of the apparatus 10 to various states during processing to govern fluid flow. The temperature controller 93 is configured to operate the heating element 80 and govern the temperature of the chemistry in the shallow dish 65 in response to a temperature sensor proximate the heating element 80.

The chemistry controller 95 governs the supply of various processing chemistries to the processing base 25 in cooperation with the drive/valve controller 90. The chemistry controller 95 may operate to: 1) regulate the content of the mixture of the processing chemistry; 2) monitor properties of the processing chemistry; 3) add constituents to the processing chemistry; 4) regenerate used chemistry for further use; and/or 5) regulate recirculation, waste treatment, and/or disposal of the processing chemistry.

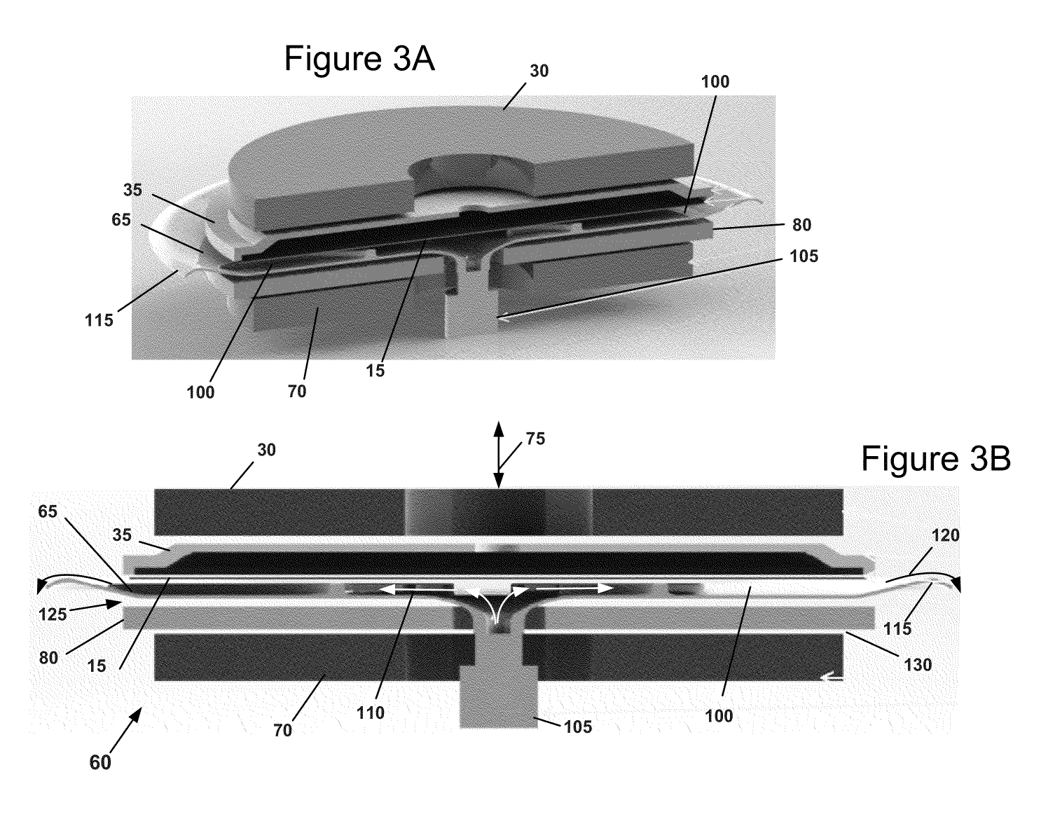

FIGS. 3A and 3B are cross-sectional views of one embodiment of the dish assembly 60 and certain portions of the wafer head 20 when the wafer head 20 is in the processing position. While in this position, the wafer 15 is in contact with the processing chemistry disposed in a basin 100 formed at the upper side of the shallow dish 65. Motor 30 rotates wafer support 35 resulting in corresponding rotation of the wafer 15 in the basin 100.

The shallow dish 65 is rotated by motor 70 while the wafer 15 is in contact with the processing chemistry. The rotation imparted to the shallow dish 65 by motor 70 is independent of the rotation imparted to the wafer 15 and wafer support 35 by motor 30. As such, the rotation of the shallow dish 65 may be at a different rate and/or direction than the rotation of the wafer 15. The relative rotation of the wafer 15 and the shallow dish 65 may be adjusted to provide even processing of the wafer for the particular type of processing operation for which apparatus 10 is designed.

A rotary union 105 is configured to receive the processing chemistry from a chemistry supply system (not shown). The rotary union 105 directs a flow of the processing fluid through a central opening of the shallow dish 65 and into the basin 100. This initial flow is shown by flow lines 110. Rotation of the shallow dish 65 by the motor 70 causes the processing chemistry to flow across the face of the wafer 15 toward its periphery under the effect of centrifugal force. At the periphery, the processing chemistry flows over a lip 115 and exits the shallow dish 65 as shown by flow lines 120. From there, the chemistry may be recirculated or handled in the manners described above with respect to the chemistry controller 95. Operation of the rotary union 105 may be governed by one or more elements of the control system 85.

The heating element 80 is disposed proximate an underside of the shallow dish 65. Both the heating element 80 and the shallow dish 65 may be disc shaped. In the illustrated example, the heating element 80 is substantially coextensive with the underside of the shallow dish 65 in that it has an upper surface having a diameter approximately the same as the diameter of the underside of the shallow dish 65. However, different geometric configurations of the heating element 80 with respect to the shallow dish 65 may likewise be used to provide the localized heating of the shallow dish 65 depending on system design requirements.

The heating element 80 may be an infrared heating element or the like, and the shallow dish 65 may be formed from a thermally conductive material, such as quartz. The heating element may be arranged so it is: 1) immediately adjacent the backside of the shallow dish 65; 2) separated from the backside of the shallow dish 65 by a fluid, such as air, in interstitial region 125; 3) separated from the backside of the shallow dish 65 by a fluid in interstitial region, where the fluid is has a high thermal conductance. Further, the heating element 80 may be configured so it is stationary with respect to the shallow dish 65, or co-rotates with the shallow dish 65. Heating element 80 may be thermally isolated from the motor 70 and other components of the dish assembly 60 by placing a thermal insulator in region 130. Further thermal isolation may be obtained by placing a thermal insulator around a periphery of the heating element 80.

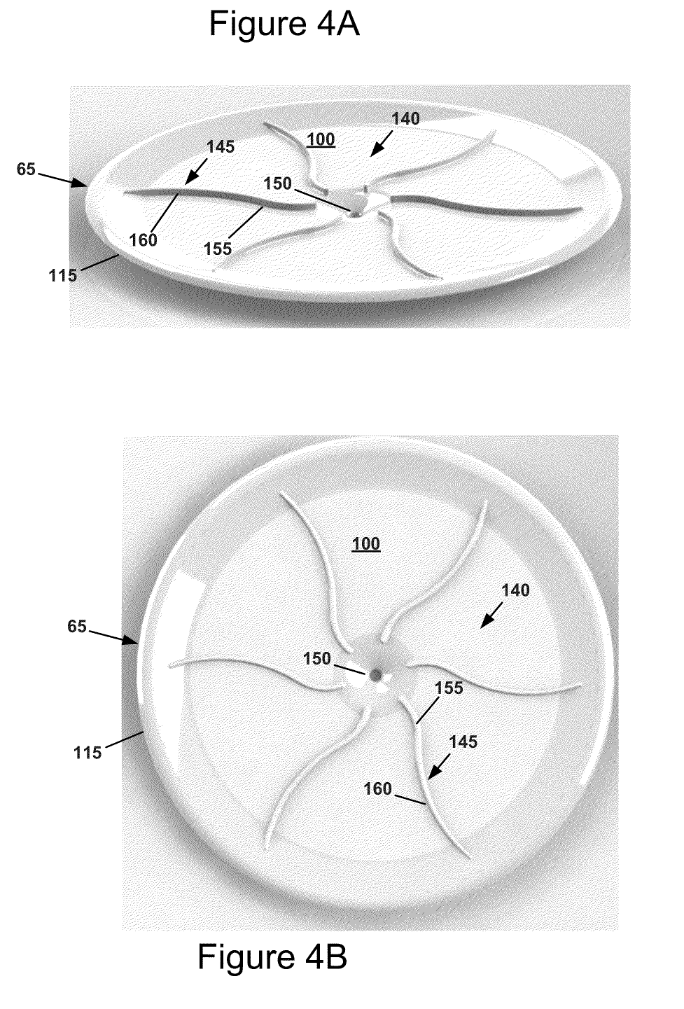

FIGS. 4A and 4B show one embodiment of a shallow dish 65. Here, basin 100 is defined by an upper surface 140 and the lip 115. A plurality of ribs 145 extend from the upper surface 140. The flow of processing chemistry is directed by the plurality of ribs 145 from a central supply opening 150, across the surface of the wafer, and over the lip 115. Here, each rib is serpentine in shape and includes a first curved section 155 and a second curved section 160 extending in a direction opposite the first curved section 155. First curved section 155 is shorter than second curved section 160 along the radius of the upper surface 140. Other configurations for directing the flow of processing chemistry through the basin 100 may also be used.

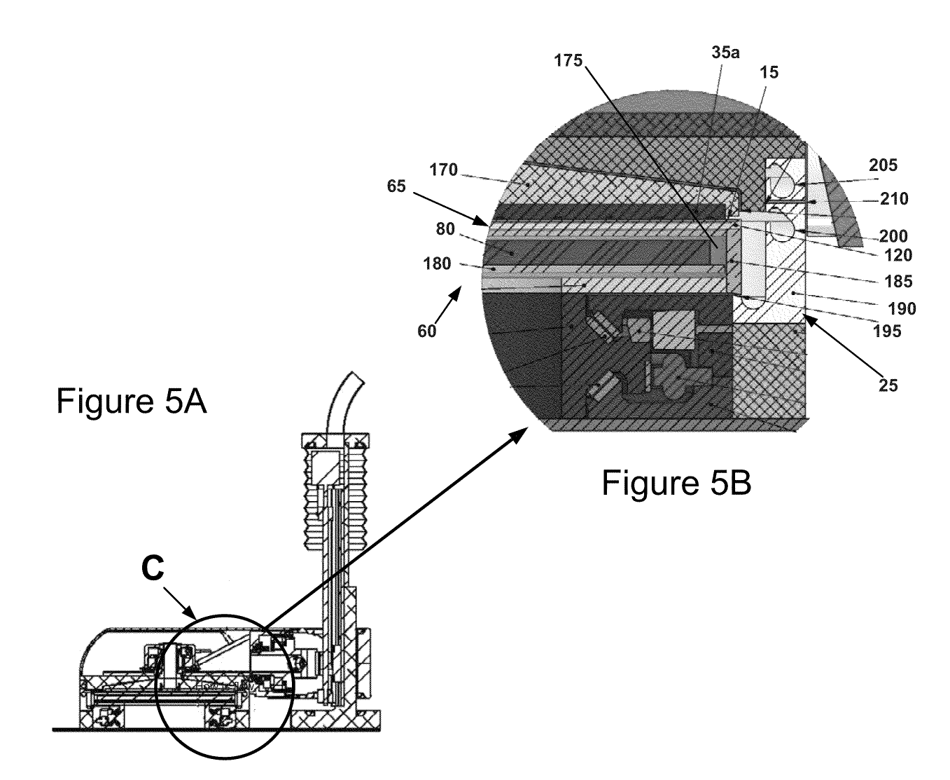

FIGS. 5A and 5B are cross-sectional views of one embodiment of section C when the wafer support 20 is in a fully engaged processing position. As shown, a support 170 is configured to engage a vacuum chuck 35a, which supports wafer 15. In the fully engaged processing position, the wafer 15 is in contact with the processing chemistry in basin 100 of the shallow dish 65. Support 170, vacuum chuck 35a, and wafer 15 are configured for co-rotation when in the fully engage processing position.

Heating element 80 is disposed in a heating chamber 175. Here, the heating chamber 175 is defined by a bottom insulating layer 180 and a side insulating layer 185. The top of the heating chamber 175 is defined by the underside of the shallow dish 65 so the heating element 80 may locally heat the shallow dish 65 and the processing chemistry in the shallow dish 65. Heating of the shallow dish 65 may be direct or indirect depending on whether the heating element 80 is in direct or indirect contact with the underside of the shallow dish 65. The bottom insulating layer 180 may be disc shaped and dimensioned to be coextensive or extend beyond the periphery of the heating element 80. Further, the side insulating layer 185 may extend about the periphery of the heating element and has a height below, level, or higher than the upper surface of the heating element 80.

The processing base 25 includes a body portion 190 having a main fluid channel 195. The main fluid channel 195 that may extend about the periphery of the processing base 25 to collect the processing chemistry overflowing lip 125. There are also two fluid catches disposed continuously or intermittently about the inner periphery of the processing base 25. A first fluid catch 200 is disposed at a first elevation of processing base 25, while a second fluid catch 205 is disposed at a second elevation.

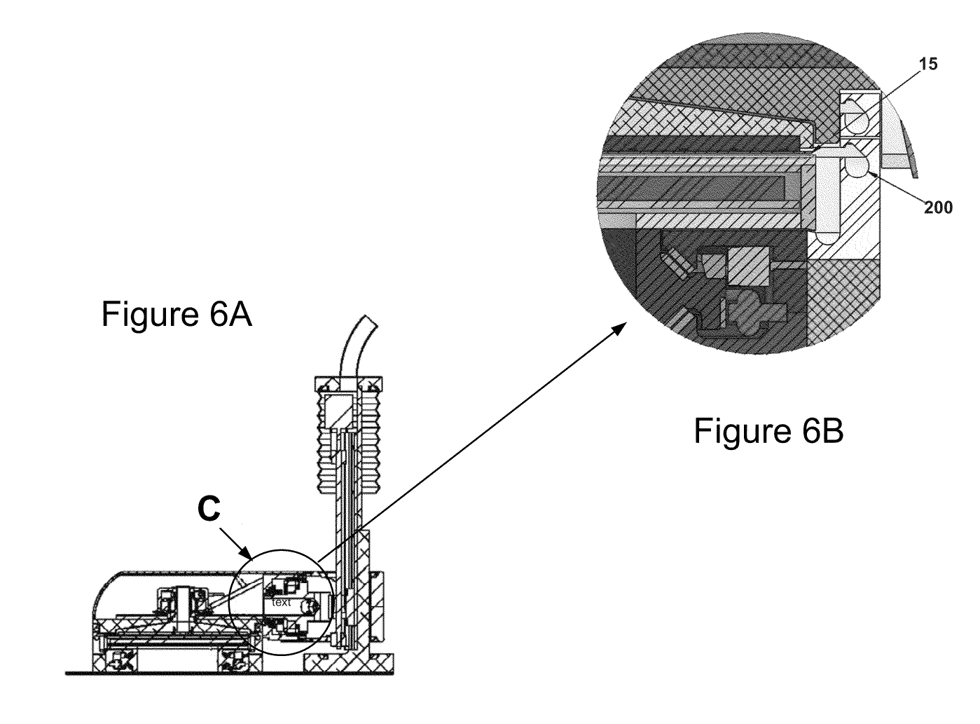

FIGS. 6A and 6B are cross-sectional views of one embodiment of section C when the wafer 15 is supported at a first intermediate processing position. In the first intermediate processing position, the wafer 15 is aligned with the first fluid catch 200. After the wafer 15 has been processed in the basin 100, the wafer head 20 may elevate the wafer 15 to the first intermediate processing position, at which point the wafer 15 is rotated to spin off residual chemistry. The residual chemistry is caught by the first fluid catch 200 and transferred, for example, to the main fluid channel 195. Alternatively, the residual chemistry caught by the first fluid catch 200 may be directed to a separate fluid channel dedicated to the residual chemistry.

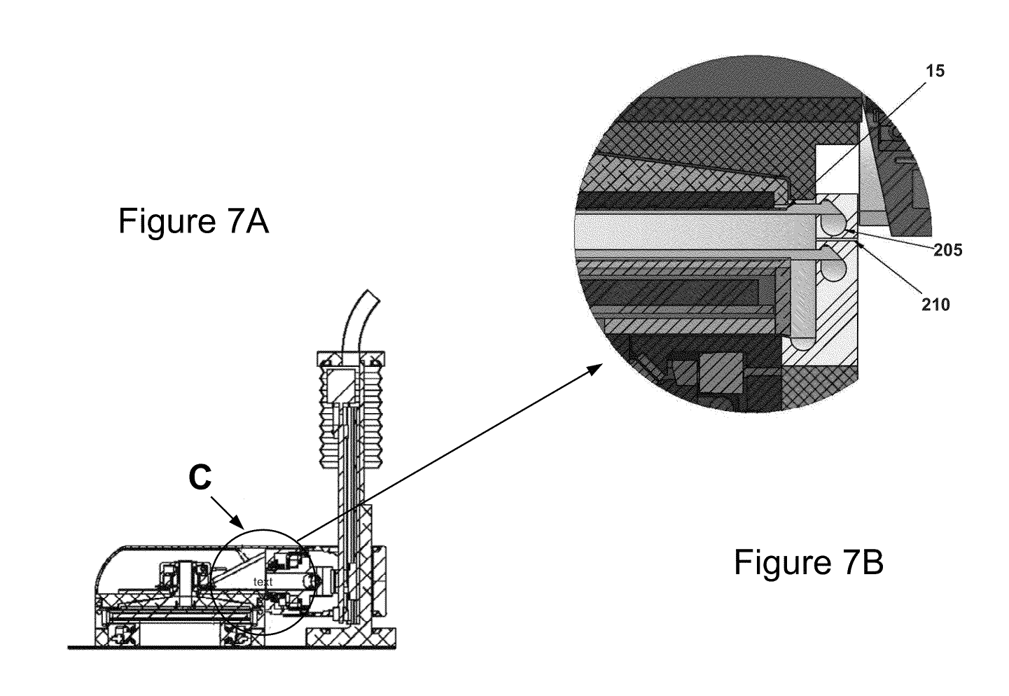

Once the residual chemistry is spun off at the first intermediate processing position, the wafer head 25 may further elevate the wafer 15 to the second intermediate processing position shown in FIGS. 7A and 7B. In the second intermediate processing position, the wafer 15 is at the same elevation as the second fluid catch 205. At this point, another processing fluid, such as a rinsing fluid, may be provided through one or more spray ports 210 disposed about the inner periphery of the processing base 25. While at this second intermediate processing position, the wafer 15 is rotated to spin off fluid communicated through the spray ports 210.

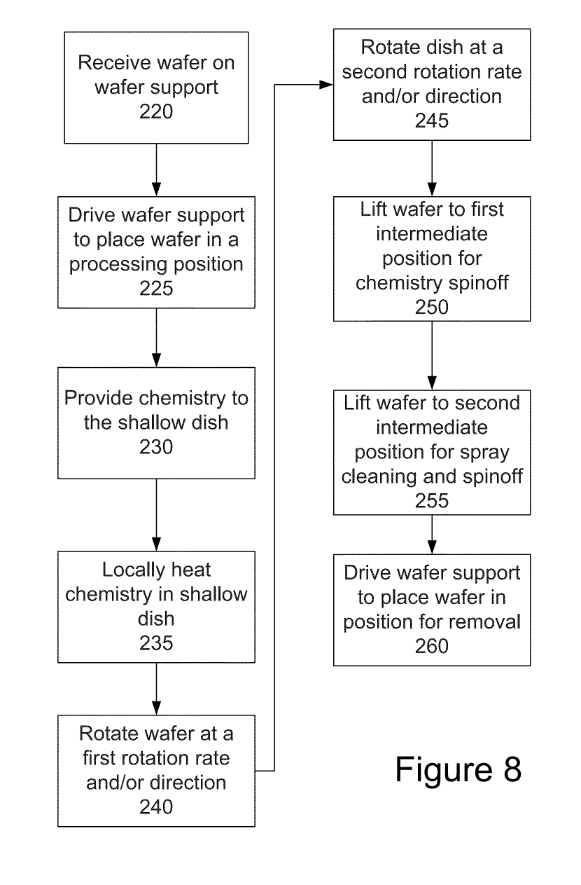

FIG. 8 is a flowchart of one manner in which a wafer may be processed. At operation 220 the wafer is received on a wafer support and subsequently driven to place the wafer in a processing position at operation 225. Chemistry is provided to a shallow dish at operation 230 and the shallow dish is locally heated to heat the chemistry. Operations 230 and 235 may take place any time prior to the actual processing of the wafer in the processing position. While in the processing position, the wafer 15 is in contact with the processing chemistry in the shallow dish and rotated at a first rotation rate and/or direction at operation 240, while the shallow dish 65 is rotated at a second rotation rate and/or direction at operation 245.

The wafer 15 may also be subject to additional processing operations in the method of FIG. 8. To this end, the wafer 15 is lifted to a first intermediate position at operation 250 to spinoff processing chemistry. At operation 255, the wafer is lifted to a second intermediate position for spray cleaning and spinoff. After the spinoff operation of 255, the wafer support is driven in operation 260 to a position in which the wafer may be removed from the support by, for example, a robotic mechanism.

1. An apparatus for processing a wafer comprising:
a wafer support configured to support a wafer in a processing position, wherein the wafer support is further configured to rotate the wafer about a first substantially vertical axis while in the processing position; and
a processing base including a shallow dish configured to receive processing chemistry, wherein the wafer support places the wafer in contact with the processing chemistry in the processing position, wherein the shallow dish is rotatable about a second substantially vertical axis when the wafer support is in the processing position, and wherein the rotation of the wafer is independent of the rotation of the shallow dish.

2. The apparatus of claim of claim 1, further comprising a heating element configured to locally heat the shallow dish.

3. The apparatus of claim 2, wherein the heating element is an infrared heating element.

4. The apparatus of claim 2, wherein the heating element is generally coextensive with an underside of the shallow dish.

5. The apparatus of claim 4, wherein the shallow dish is formed from a thermally conductive material.

6. The apparatus of claim 5, wherein the shallow dish is formed from quartz.

7. The apparatus of claim 2, wherein the heating element has a generally disc shape.

8. The apparatus of claim 7, wherein the heating element has a first side generally coextensive with an underside of the shallow dish, and a second side proximate an insulating material.

9. The apparatus of claim 1, wherein the processing base comprises a fluid channel configured to collect processing chemistry overflowing a periphery of the shallow dish.

10. The apparatus of claim 1, wherein the wafer support and the shallow dish are configured for rotation about the same axis.

11. A processing base for a wafer processing apparatus, the processing base comprising:
a shallow dish configured to receive processing chemistry, wherein the shallow dish is dimensioned to receive a wafer for contact with the processing chemistry; and
a motor configured to rotate the shallow dish about a substantially vertical axis.

12. The processing base of claim of claim 11, further comprising a heating element configured to locally heat the shallow dish.

13. The processing base of claim 12, wherein the heating element is an infrared heating element.

14. The processing base of claim 12, wherein the heating element is generally coextensive with an underside of the shallow dish.

15. The processing base of claim 14, wherein the shallow dish is formed from a thermally conductive material.

16. The processing base of claim 15, wherein the shallow dish is formed from quartz.

17. The processing base of claim 12, wherein the heating element has a generally disc shape.

18. The processing base of claim 17, wherein the heating element has a first side generally coextensive with an underside of the shallow dish, and a second side proximate an insulating material.

19. The processing base of claim 11, wherein the processing base comprises a fluid channel configured to collect processing chemistry overflowing a periphery of the shallow dish.

20. A method for processing a wafer comprising:
receiving a wafer on a wafer head;
driving the wafer head to place the wafer in a processing position for contact with chemistry disposed in a shallow dish;
rotating the wafer while in the shallow dish; and
rotating the shallow dish at a different rotation rate and/or direction from rotation of the wafer.

21. The method of claim 20, further comprising heating the chemistry in the shallow dish using a heating element disposed at an underside of the shallow dish.

22. The method of claim 20, further comprising heating the chemistry using a heating element disposed substantially adjacent to and coextensive with an underside of the shallow dish.
